(19) United States
(12) Patent Application Publication
(10) Pub. No.: US 2009/0001524 A1
(43) Pub. Date: Jan. 1, 2009

(54) GENERATION AND DISTRIBUTION OF A FLUORINE GAS

(76) Inventors: Stephen H. Siegele, Austin, TX (US); Frederick J. Siegele, Austin, TX (US)

Correspondence Address: SPRINKLE IP LAW GROUP, 1301 W. 25TH STREET, SUITE 408, AUSTIN, TX, 78705, US

(21) Appl. No.: 12/181,982

(22) Filed: Jul. 29, 2008

Related U.S. Application Data
(63) Continuation of application No. 10/283,433, filed on Oct. 30, 2002.
Application No. 10/283,433 is a continuation-in-part of application No. 10/193,864, filed on Jul. 12, 2002, now abandoned.
(60) Provisional application No. 60/333,405, filed on Nov. 26, 2001.

(51) Int. Cl. H01L 23/58; H01L 21/302; C23F 1/08; B44C 1/22; H05H 1/24; H01L 21/31

(52) U.S. Cl. 257/632; 118/723 R; 156/345.33; 216/67; 427/569; 438/710; 438/758; 257/E21.214; 257/E21.24; 257/E23.002

(57) ABSTRACT

Molecular fluorine may be generated and distributed on-site at a fabrication facility. A molecular fluorine generator may come in a variety of sizes to fit better the needs of the particular fabrication facility. The generator may service one process tool, a plurality of process tool along a process bay, the entire fabrication facility, or nearly any other configuration within the facility. The process can obviate the need and inherent risks with transporting or handling gas cylinders. The process can be used in conjunction with a cleaning or fabrication operation used in the electronics fabrication industry.

### RELATED APPLICATIONS

This application claims priority under 35 U.S.C. § 119(e) to U.S. Patent Application No. 60/295,646 entitled “System and Method for Generating a Non-Ozone Depleting Material” by Jackson et al. filed Nov. 26, 2001. This application also claims priority under 35 U.S.C. § 120 to U.S. patent application Ser. Nos. 10/038,745 entitled “Method And System For On-Site Generation And Distribution Of A Process Gas” by Jackson filed Jan. 2, 2002, and 10/193,864 entitled “Method And System For On-Site Generation And Distribution Of Fluorine for Fabrication Processes” by Siegele et al. filed Jul. 12, 2002. All applications cited within this paragraph are assigned to the current assignee hereof and are incorporated herein by reference.

### TECHNICAL FIELD

The present invention generally relates to processes related to fluorine-containing compounds, and more particularly, to methods for on-site generation and distribution of fluorine-containing compounds for cleaning and other fabrication processes.

### DESCRIPTION OF THE RELATED ART

A variety of fluorine-containing gases are used during fabrication or cleaning processes. For example, nitrogen trifluoride (NF₃) gas may be used to etch substrates or clean chambers of processing tools used in deposition processes. Some conventional fabrication deposition processes include depositing layers of materials using Chemical Vapor Deposition (CVD), such as Low Pressure Chemical Vapor Deposition (LPCVD), Plasma Enhanced Chemical Vapor Deposition (PECVD), Vapor Phase Epitaxy (VPE), Metalorganic Chemical Vapor Deposition (MOCVD), and the like, or Physical Vapor Deposition (PVD), such as evaporation, sputtering, and the like.

A variety of methods are used to etch substrates or clean chambers. In one embodiment, a plasma including NF₃ can be used to react with a deposited material on the substrate or on the walls of the chamber.

Typically, the NF₃ is made at a chemical plant and shipped in gas cylinders to the fabrication facility. The transportation and handling of gas cylinders can involve many safety issues, including physical concerns (exploding cylinders, “torpedoes” (snapped off pressure regulator), and the like), health concerns (human, animal, or plant exposure to the contents of the gas cylinder), and chemical concerns (reaction with air or other nearby chemicals). Additionally, some gasses may have a limited shelf life and may not be used before the gas cylinder is depleted. Still further, some gasses may not be able to withstand temperatures during transportation, which may be potentially as high as approximately 70 degrees Celsius.

### SUMMARY

Molecular fluorine may be generated and distributed on-site at a fabrication facility. A molecular fluorine generator may come in a variety of sizes to fit better the needs of the particular fabrication facility. The generator may service one process tool, a plurality of process tool along a process bay, the entire fabrication facility, or nearly any other configuration within the facility. The process can obviate the need and inherent risks with transporting or handling gas cylinders. The process can be used in conjunction with a fabrication or cleaning operation. The process is particularly well suited for cleaning deposition chambers as used in the microelectronics industry.

In one set of embodiments, a process for generating and using a fluorine-containing compound can comprise reacting a fluorine-containing reactant in a first reactor to form a fluorine-containing compound. The process can also comprise flowing the fluorine-containing compound to a second reactor. The first and second reactors can be located on-site at the same fabrication facility.

In another set of embodiments, a process for using a process tool can comprise placing a substrate within a chamber of the process tool and reacting a fluorine-containing reactant in a reactor to form molecular fluorine. The process can also comprise generating a fluorine-containing plasma from the molecular fluorine. The generation may be performed in a plasma generator that is located outside the chamber. The process can further comprise flowing the fluorine-containing plasma to the chamber while the substrate is in the chamber. Reacting and flowing may be performed simultaneously during at least one point in time.

In a further set of embodiments, a process for cleaning a chamber can comprise flowing molecular fluorine into a chamber and generating a fluorine-containing plasma using the molecular fluorine. The fluorine-containing plasma can be generated within the chamber.

The foregoing general description and the following detailed description are exemplary and explanatory only and are not restrictive of the invention, as defined in the appended claims.

### BRIEF DESCRIPTION OF THE DRAWINGS

The present invention is illustrated by way of example and not limitation in the accompanying figures.

FIG. 1 includes an illustration a system for on-site generation and distribution of molecular fluorine according to an embodiment described herein.

FIG. 2 includes an illustration of a fluorine generator that can be used at a fabrication facility.

FIG. 3 includes a process flow diagram for the on-site generation and distribution of a fluorine-containing compound according to an embodiment described herein.

FIGS. 4 and 5 includes process flow diagrams for generating and using a fluorine-containing compound according to embodiments described herein.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Reference is now made in detail to the exemplary embodiments of the invention, examples of which are illustrated in the accompanying drawings. Wherever possible, the same reference numbers will be used throughout the drawings to refer to the same or like parts (elements).

Molecular fluorine may be generated and distributed on-site at a fabrication facility. In particular, the on-site generated fluorine may be used for process chamber cleaning in a microelectronic fabrication facility. A molecular fluorine generator may come in a variety of sizes to fit better the needs of the particular fabrication facility. The generator may service one process tool, a plurality of process tool along a process bay, the entire fabrication facility, or nearly any other configuration within the facility. The process can obviate the need and inherent risks with transporting or handling gas cylinders. Therefore, the safe delivery of hazardous materials for fabrication processes at a fabrication facility. The process can be used in conjunction with a fabrication or cleaning operation.

A few terms are defined or clarified to aid in understanding the descriptions that follow. The term “fabrication facility” is intended to a facility where microelectronic components, assemblies, or modules are fabricated. An example can include a semiconductor wafer fabrication facility, an integrated circuit assembly or packaging facility, a microelectronic module assembly facility, thin-film transistor liquid crystal or flat panel display fabrication facility, or the like. Fabrication facility is not intended to include a chemical plant, plastics manufacturing facility (where microelectronic devices are not produced), or nuclear fuel processing plant within its definition.

The term “lot” is intended to mean a unit comprising a plurality of substrates that are processed together (substantially at the same time or sequentially) through the same or similar process operations. Within a fabrication facility, substrates are usually processed on a lot-by-lot basis. The size of a lot may vary, but are usually no greater than approximately 50 substrates.

The term “molecular fluorine” is intended to mean a molecule that only contains fluorine atoms. Diatomic fluorine (F₂) is an example of molecular fluorine.

The term “process bay” is intended to mean a room of a fabrication facility where substrates may be transported between process tools.

The term “process tool” is intended to mean a piece of equipment that has at least one reactor in which substrates are capable of being processed.

The term “reactor” is intended to mean an apparatus where chemical bonds are changed. Chemical bonds may be made or broken (decomposition or plasma generation). An example includes an electrolytic cell, a process chamber, plasma generator, or the like. A non-limiting example of a process chamber includes a semiconductor process chamber, such as a chemical or physical vapor deposition chamber.

The term “utility bay” is intended to mean an area adjacent to a process bay where utilities are supplied to process tools, and where mechanical service to the process tools may be made without entering the process bay. The utility bay can be located between immediately adjacent process bays or below the process bay. The process bays may be located within a clean room, and utility bays may be located may be located outside the clean room or within the clean room but at a location not as clean as the process bays.

As used herein, the terms “comprises,” “comprising,” “includes,” “including,” “has,” “shaving” or any other variation thereof, are intended to cover a non-exclusive inclusion. For example, a process, process, article, or apparatus that comprises a list of elements is not necessarily limited only those elements but may include other elements not expressly listed or inherent to such process, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Attention is now directed to details of non-limiting embodiments. An electrolytic process may be used for on-site generation of molecular fluorine. In one embodiment, the on-site generation of fluorine can be accomplished using a fluorine generator as described in U.S. patent application Ser. No. 10/038,745 entitled “Method and System for On-Site Generation and Distribution of a Process Gas.” A distribution system may be coupled to the fluorine generator and operable to distribute the molecular fluorine to one or more process tools. Molecular fluorine may be used with or without a plasma as an aggressive agent during a semiconductor process or cleaning operation and may be advantageous over conventional chemicals or gas compositions due to the absence of fluorocarbons. However, in some embodiments, the molecular fluorine may be used in conjunction with a fluorocarbon or other etching compound.

Some embodiments may include using molecular fluorine to reduce processing time associated with fabricating a semiconductor device. Additionally, the molecular fluorine may be used during the fabrication of components, assemblies, devices, such as microelectronic devices, integrated microelectronic circuits, ceramic substrate based devices, flat panel displays, or other devices. Many of these components, assemblies and devices include one or more microelectronic device substrates. Examples of microelectronic device substrates include semiconductor wafers, glass plates for use in thin-film transistor (“TFT”) displays, substrates used for organic light-emitting diodes (“OLEDs”), or other similar substrates commonly used in the fabrication of microelectronic devices.

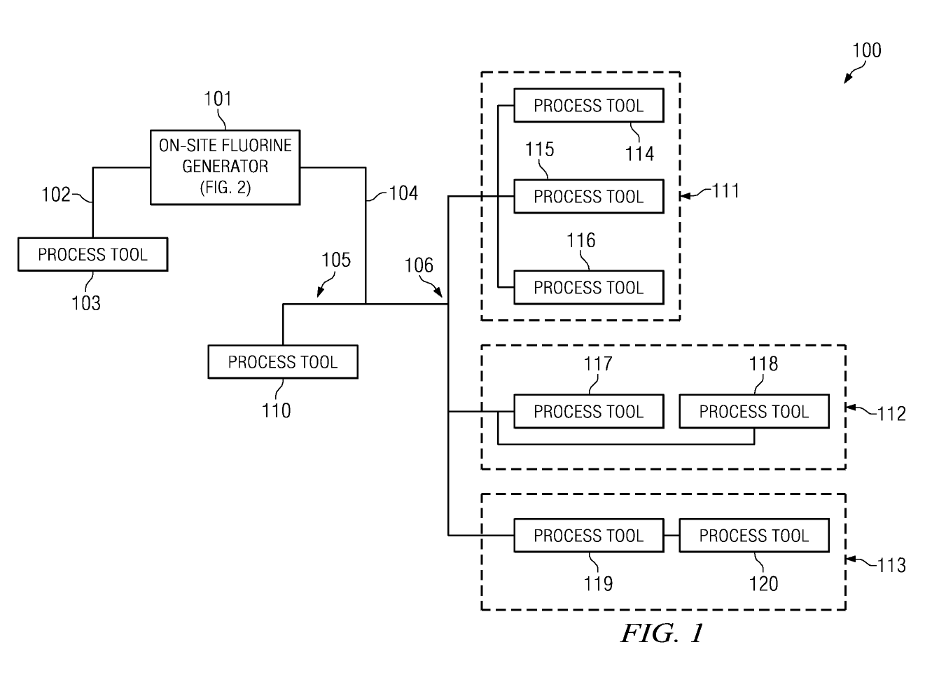

FIG. 1 includes an illustration of a system for on-site generation and distribution of molecular fluorine. The system, illustrated generally as 100, can include an on-site molecular fluorine generator 101 can be fluidly coupled to a first distribution line 102 and a second distribution line 104 operable to distribute molecular fluorine within a fabrication facility. Distribution lines, illustrated in FIG. 1, may include associated tubing, plumbing, fittings, and fluid transfer or control devices such as pumps, valves, etc. configured to flow molecular fluorine within the fabrication facility. For example, first distribution line 102 may be a double-lined distribution line designed to flow hazardous materials safely to a reactor (e.g., a plasma generator or a chamber of a process tool), a system, or a process bay. In one embodiment, system 100 may be located proximal or distal to a plurality of process tools that may use molecular fluorine. Process tool 103 may be coupled to on-site fluorine generator 101 via first distribution line 102. On-site molecular fluorine generator 101 may further be coupled to second process tool 110 via second distribution line 104 and single tool distribution line 105.

On-site molecular fluorine generator 101 may also be coupled to a multi-port distribution line 106 via second distribution line 104. Multi-port distribution line 106 may be coupled to several process bays that use molecular fluorine for various fabrication or cleaning processes. For example, multi-port distribution line 106 may be coupled to a first process bay 111 having process tools 114, 115, and 116. The first process bay may be for thin-film deposition, ion implant, etch, or lithography.

Multi-port distribution line 106 may also be coupled to a second process bay 112 that may include process tools 117 and 118, which may use molecular fluorine. The process tools 117 and 118 may be coupled in a parallel configuration and may be operable as identical or different tools. For example, second process bay 112 may be a deposition processing bay having a plurality of deposition processing tools. As such, on-site molecular fluorine generator 101 may provide second process bay 112 with molecular fluorine for cleaning deposition chambers of tools 117 and 118. The cleaning may be performed between each substrate processed in a chamber, or between each lot, or any other interval.

Multi-port distribution line 106 may further be coupled to a third process bay 113 that may include process tools 119 and 120. Process tool 120 can be serially connected to process tool 119.

In one non-limiting specific embodiment, the distance between the fluorine generator 101 may be no more than approximately 200 meters from each of the process tools connected to it. The fabrication facility may include a plurality of generators similar to fluorine generator 101. Because fluorine generator 101 may be compact and portable, fluorine generator 101 may be less than approximately 50 meters from all process tools to which it is connected or coupled. In other words, fluorine generator 101 can be as close to any particular process tool as the physical bodies of the fluorine generator 101 and a process tool will allow. Fluorine generator 101 may be dedicated to a single process tool or automatically to a process bay. Alternatively, one fluorine generator 101 may service two or more adjacent process bays. Typically, the generator may be located within a utility bay adjacent to a process bay that it services. In still another embodiment, the fluorine generator 101 may lie between and service two adjacent process bays. In still another embodiment, the fluorine generator 101 may be moved from process tool to process tool as needed. After reading this specification, skilled artisans appreciate that many other configurations are possible.

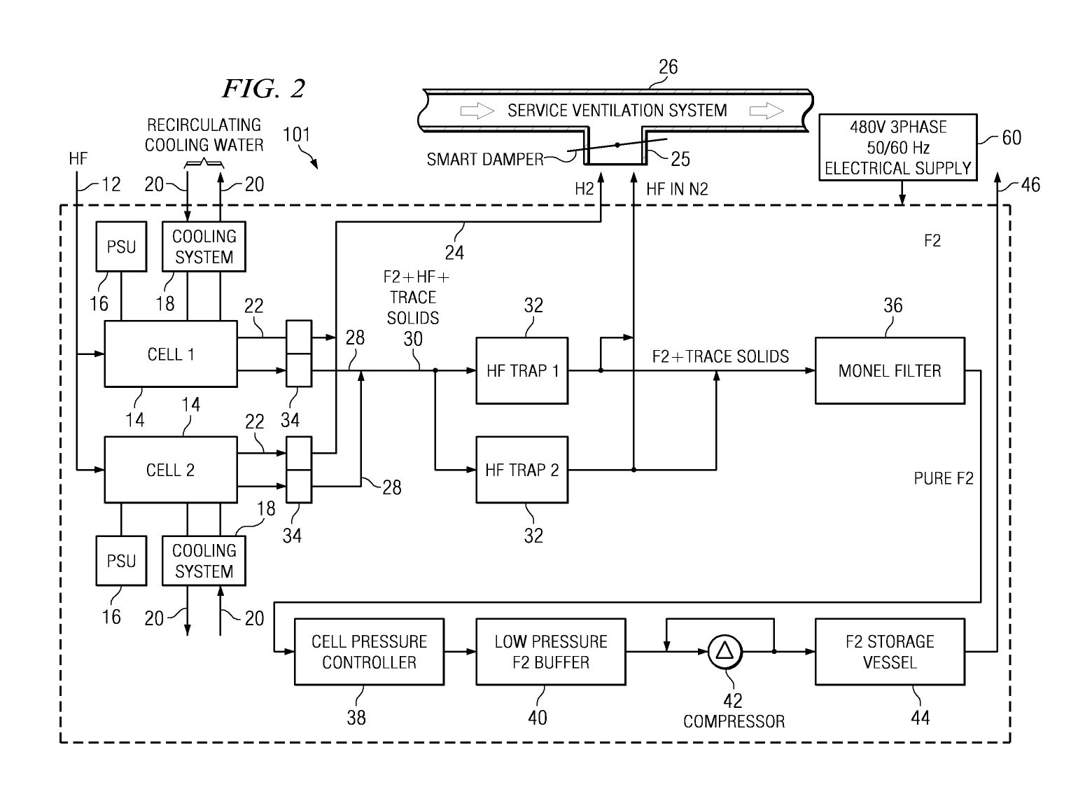

An exemplary embodiment of the molecular fluorine generator 101 is shown in more detail in FIG. 2. FIG. 2 includes a simplified block diagram of fluorine generator 101. Process gas generation system 101 can include input supply line 12 to process gas generation cells 14. In one embodiment, input supply line 12 can be used to supply hydrogen fluoride (HF) to an electrolyte within process gas generation cells 14. The process gases generated by process gas generation cells 14 can include diatomic hydrogen (H₂) at one electrode of the electrolytic cell and diatomic fluorine (F₂) at the other electrode of the electrolytic cell. The electrolyte within process gas generation cells 14 can include potassium fluoride (KF).

Each process gas generation cell 14 can be coupled to a pressure-sensing unit 16 and a cooling system 16. Pressure sensing unit 16 monitors the pressure within a process generation cell 14. Cooling system 16 provides cooling to its respective process generation cell 14 using recirculating cooling water through cooling water lines 20.

Hydrogen is output from each process gas generation cell 14 along hydrogen output line 22. Combined hydrogen output header 24 is coupled to and receives hydrogen from each hydrogen output line 22. Hydrogen output header 24 is coupled to exhaust system 25. Hydrogen is routed to exhaust system 25 and then to service ventilation system 26, which exhausts the hydrogen to the outside atmosphere.

The diatomic fluorine process gas, including small amounts of HF and solids, can be output from process gas generation cells 14 along process gas output lines 28 to a combined process gas output header 30. Each process gas generation cell 14 can further comprise an output manifold 34. The diatomic fluorine can flow through an output manifold 34 and to a combined gas output header 30. The process gas generation system 100 can further comprise various valves operable in various open/closed combinations, to direct process gas from each manifold 34 to one or another (or to multiple) sodium fluoride (NaF) traps 32. The sodium fluoride (NaS) traps 32 can be used to remove residual HF from the process gas stream. The NaF traps 32 may also be referred to as HF getters. Although FIG. 2 shows only two NaF traps 32, other embodiments can comprise multiple NaF traps. In operation, one NaF trap 32 can always be on-line, with the other NaF trap 32 (or other ones) regenerating or being maintained. During regeneration, HF can be emitted from directed to a ventilation system.

During normal operation, the output of NaF traps 32 includes diatomic fluorine gas, including a small amount of solids. This gas stream flows to a Monel output filter 36 to remove the solids. The effluent from filter 36 should be nearly all F₂ gas. The filtered gas may be sequentially forwarded to cell pressure controller 38 and then to low-pressure buffer tank 40. Cell pressure controller 38 can cycle process gas generation cells 14 on and off based on process gas demand as measured at the input to low-pressure buffer tank 40.

After tank 40, the F₂ gas can be provided to compressor 42. Compressor 42 can be coupled to a low-pressure buffer tank 40 and, at its output, to process gas storage tank 44. Compressor 42 can compress the F₂ gas to, for example, approximately 100 kPa (or 15 psig) in process gas storage tank 44. From process gas storage tank 44, the process gas can be provided from the output line 46 to any one or more of the distribution lines 102, 104, 105, or 106 as seen in FIG. 1.

The generator illustrated in FIG. 2 is exemplary of just one embodiment of an on-site reactor capable of producing F₂ gas. After reading this specification, skilled artisans appreciate that many other alternatives may be used.

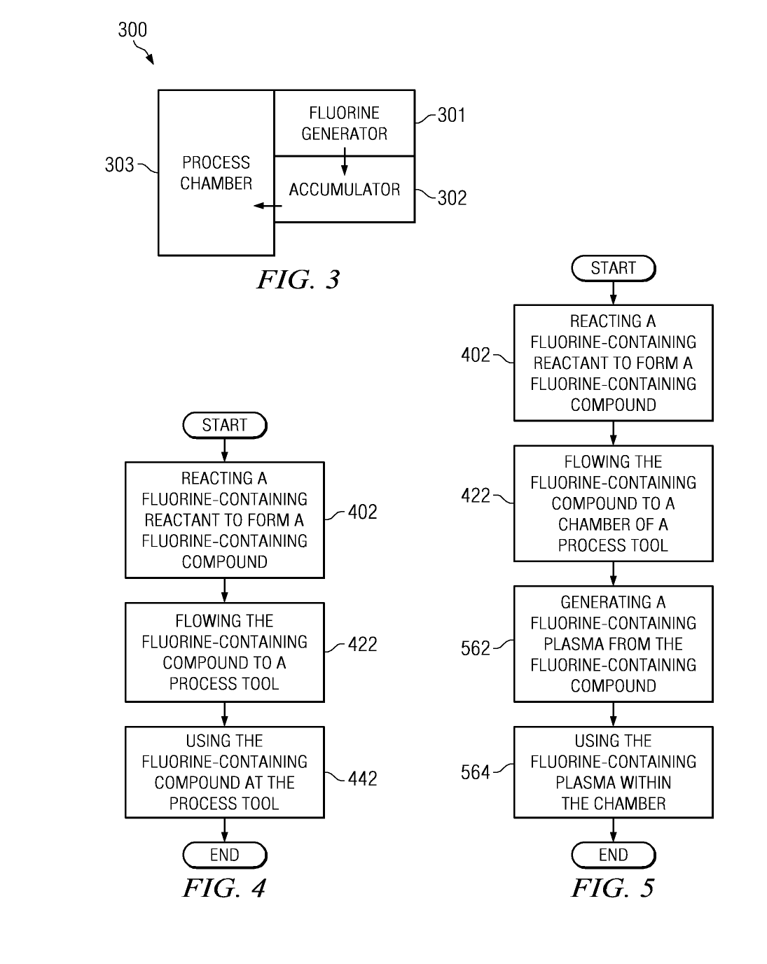

FIG. 3 includes an illustration a process tool 300 having a local (at the tool) fluorine generator. The process tool, illustrated generally as 300, includes a molecular fluorine generator 301 operable to generate molecular fluorine for use in association with a fabrication process. Generator 301 can be coupled to an accumulator 302 that is coupled to a process chamber 303 used in fabricating a device, such as a semiconductor device. In one non-limiting embodiment, system 300 may be configured as an etch tool capable of etching a substrate using molecular fluorine as part of an etch species. As such, molecular fluorine may react with regions of a substrate to provide etched locations of the substrate.

In another embodiment, system 300 may be configured as deposition process tool capable of depositing a thin layer of material (e.g., dielectric layer, conductive layer, barrier layer, etc.) over a substrate. As such, molecular fluorine may be introduced during or after the deposition to remove undesirable contaminants from a process chamber associated with system 300. Alternatively, the molecular fluorine may be used to remove a deposited material before it becomes too thick and starts to generate particles as it begins to peel due to stress within the deposited film. In this manner, molecular fluorine may be used to remove undesirable contaminants, metals, compounds, by-products, or other materials from a deposition process.

In an alternate embodiment, the accumulator 302 can be used to locally store molecular fluorine at the process tool 300, where the molecular fluorine is generated elsewhere within the fabrication facility and flows to the process tool 300 through the distribution lines previously described. The process tool 300 may further comprise a controller to monitor the accumulator 302 and replenish the molecular fluorine at least to a desired level.

FIG. 4 includes a process flow diagram in accordance with one embodiment. The process may be used in association with the system illustrated in FIG. 1. The method can comprise reacting a fluorine-containing reactant to form a fluorine-containing compound (block 402). Referring to FIG. 2, HF, which can be a fluorine-containing reactant can be decomposed within either or both of the electrolytic cells 14. The decomposition produces H₂ gas and F₂ gas, which is a fluorine-containing compound. The process can further comprise flowing the fluorine-containing compound (F₂ gas) to a process tool (block 422). The process tool can comprise a chamber, in which the F₂ gas may be used in a reaction within the chamber. The process can further comprise using the fluorine-containing compound at the process tool (block 424). In non-limiting examples, the F₂ gas can be used to etch a substrate within the chamber or to clean the chamber by removing material that has deposited along walls or other surfaces inside the chamber (e.g., substrate handler, deposition shields, clamps, etc.). Fluorine can be useful for removing silicon-containing or metal-containing materials from the chamber, such as dielectrics, metals, metal silicides, and the like.

FIG. 5 includes a process flow diagram for a process similar to FIG. 4. However, unlike FIG. 4, FIG. 5 contemplates the use of a plasma. The process can include the reacting and flow acts (blocks 402 and 422) as previously described. The process can further comprising generating a fluorine-containing plasma from the fluorine-containing compound (block 562). The plasma may be generated using a conventional technique to form neutral fluorine radicals (F.) and ionic fluorine radicals (F⁺, F⁻, F₂⁺, F₂⁻, or any combination thereof).

The plasma may be generated within a chamber of the process tool or outside the chamber. In the latter, a plasma generator may be connected between the distribution lines and specific process tool where the fluorine-containing plasma is to be provided. In one specific embodiment, the plasma generator may be part of or attached to the process tool.

The process can further comprising using the fluorine-containing plasma within the chamber of the tool (block 564). The fluorine-containing plasma may be used in manners similar to those previously described with block 442 in FIG. 4 (e.g., etching substrates, cleaning deposition chambers, or the like).

In another embodiment, the process may further comprise recycling the unused molecular fluorine gas. As such, a recycle system (not shown) may receive the unused molecular fluorine and recycle the molecular fluorine gas such that unwanted contaminants within the molecular fluorine gas may be removed and the molecular fluorine may be reused for subsequent processing. The recycled molecular fluorine may be used in association with a distribution system to reduce the amount of new molecular fluorine gas needing to be produced by the electrolytic cells 14 in FIG. 2.

### EXAMPLES

### Plasma Etch Example

An aluminum-containing layer can be formed to a thickness of approximately 800 nm. After subsequent patterning, bond pads having areal dimensions of 15 microns by 15 microns, nominally, may be formed. A passivation layer may be formed over the bond pads and have a thickness of approximately 900 nm. The passivation layer may comprise approximately 200 nm of silicon oxide and approximately 700 nm of silicon nitride. One or both of the silicon oxide and silicon nitride layers may be formed using plasma-enhanced chemical vapor deposition.

A patterned photoresist layer can be formed over the passivation layer. In one non-limiting embodiment, the photoresist layer may be JSR positive photoresist material available from JSR Company of Japan and has a thickness of approximately 3500 nm. The patterned photoresist comprise opening over the bond pads.

The passivation layer can be etched with an etchant gas composition comprising diatomic fluorine (F₂), carbon tetrafluoride (CF₄), trifluoromethane (CHF₃), argon (Ar), and sulfur hexafluoride (SF₆). Note that the diatomic fluorine may have been previously generated at the fabrication facility where the etching is taking place. The etch can be performed to expose the bond pads. The plasma may be formed within an Applied Materials MxP+ brand tool from Applied Materials, Inc. of Santa Clara, Calif. The tool may be operated under the following conditions: (1) a reactor chamber pressure of approximately 150 mtorr; (2) a source radio frequency power of approximately 0 watts at a source radio frequency of 13.56 MHZ (i.e., without a bias power); (3) a semiconductor substrate temperature of approximately 250 degrees Celsius; and (4) an oxygen flow rate of approximately 8000 standard cubic centimeters per minute (sccm).

During the etch operation, via veils may be formed along the sidewalls of the bond pads and may include a fluorocarbon polymer residue that may or may not include aluminum. The via veils can be stripped from the semiconductor substrates through immersion within a stripping solvent comprising monoethanolamine available as ACT (from Ashland Specialty Chemical Division of Ashland, Inc. or Covington, Ky.) or EKC (from EKC Technology Inc. of Hayward, Calif.) stripper.

### Plasma Cleaning Process Example

In a more specific exemplary process, a gas capable of reacting with the deposits to be removed may be flowed into a space to be cleaned, e.g., the vacuum deposition chamber. The deposits may be a silicon-containing material, a metal containing material (e.g., a metal, a metal alloy, a metal silicide, etc.) or the like. The gas can be excited to form a plasma within the chamber or remote to the chamber. If formed outside the chamber, the plasma can flow to the chamber using a conventional downstream plasma process. The plasma or neutral radicals generated from the plasma can react with the deposits on the exposed surfaces within the chamber.

The gas employed in the etching process typically is a gaseous source of a halogen. The gaseous source may include F₂, NF₃, SF₆, CF₄, C₂F₆ combinations thereof, or the like. Additionally, chlorine-containing or bromine-containing gases may be used. In a non-limiting specific embodiment, F₂ may have previously been generated at the fabrication facility where the chamber clean is taking place. Nearly any mixture of the gases described in this paragraph may also be employed. An inert or noble diluent gas including argon, neon, helium, or the like, can also be combined with the gas or mixture of gases.

After reading this specification, skilled artisans are capable of determining an appropriate flow rate of the gas (or gases), temperature and pressure conditions within the vacuum deposition chamber or other space by taking into account the volume of space from which deposits are to be removed, the quantity of deposits to be removed, and potentially other factors. If needed, a conventional purging act may be performed after the etching or cleaning gases are used to remove the deposits. Typical process parameters are set forth in U.S. Pat. No. 5,207,836 (“Chang”), which is incorporated herein by reference.

In one non-limiting embodiment, tungsten may be deposited within a chamber, and diatomic fluorine may be used to remove the tungsten that deposits on the interior walls and internal parts of the chamber. The diatomic fluorine may be generated at the fabrication facility where the tungsten deposition occurs.

Turning to the deposition portion, a silicon wafer can be introduced into the vacuum deposition chamber of a Precision 5000 xZ apparatus available from Applied Materials, Inc. The chamber can be heated to a processing temperature of approximately 475° C. After conventional pre-nucleation with tungsten hexafluoride (WF₆) and silane (Si₄), chamber purge pressurization and stabilization of the wafer on the heater plate, tungsten can be deposited carried out using WF₆ at a flow rate approximately 95 sccm at a pressure of approximately 90 Torr. After removing the wafer, the chamber may be purged and pumped (Ar/N₂/H₂ purge). The deposition process may be repeated until approximately 25 silicon wafers are processed.

After the deposition, the chamber may need to be cleaned to remove the deposits that have built up during the processing of the wafer. The deposition chamber can be heated to a temperature of approximately 475° C. for a period of 23 seconds. An aluminum nitride wafer may be inserted to protect a wafer chuck where wafers would normally reside during the deposition process. Concurrently or subsequently, F₂ can be introduced into the chamber at approximately 150 sccm and a base pressure of approximately 300 mTorr. A plasma can be formed from the F₂ gas. During a first portion of the cleaning process, the plasma power may be maintained at approximately 600 watts for approximately 230 seconds. During a first portion of the cleaning process, the plasma power may be maintained at approximately 200 watts for approximately 220 seconds. After two purge/pump cycles (each cycle including approximately 30 seconds of Ar/N₂/H₂ purge, and approximately three seconds of pumping (evacuating), the chamber has been clean. At this time, the deposition procedure can be repeated.

The chamber cleaning may be performed between substrates (e.g., silicon wafers), between lots of substrates, or at nearly any interval. The timing of the cleaning may depend on the stress of the film being deposited and its thickness.

The processes previously described can provide advantages over conventional processes and may be applicable to many different fabrication industries. One example includes a process tool having a diffusion furnace tube that needs cleaning. Molecular fluorine can be produced on-site at a fabrication facility, thereby obviating the need to transport gas cylinders from a chemical plant. If gas cylinders would be used the gas cylinders could become damaged or other fail to contain the gas, a large amount of gas may be released into the atmosphere and cause significant damage. Also, some materials, such as molecular fluorine, may have a limited shelf life. By producing the molecular fluorine on-site, the transportation hazards are avoided.

Further, molecular fluorine may be produced in smaller amounts or on an as-needed basis. Should there be an accidental release of molecular fluorine, it will be a relatively smaller amount compared to a gas cylinder, and the exhaust system of the fabrication facility may be better suited to handle the smaller amounts. Therefore, embodiments can be used for a safe generation and distribution system for hazardous materials, such as molecular fluorine.

Additionally, the generator can be portable and moved from process bay to process bay, from utility bay to utility bay, or from process tool to process tool. Expensive plumbing for hazardous materials may be reduced. Also, the number of generators can be better tailored to the needs of the facility.

The on-site molecular fluorine generator may be located proximal, distal, or integrated as a part of a process tool. Such flexibility allows configurations to be specifically adapted to the specific needs of a particular fabrication facility.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

What is claimed is:

1-36. (canceled)

37. A system comprising:
a hydrofluoric acid (HF) source operable to supply HF;
at least one electrolytic cell fluidly coupled to the HF source, the at least one electrolytic cell operable to produce a process gas comprising diatomic fluorine from HF;
at least one purification module fluidly coupled to the at least one electrolytic cell, the at least one purification module operable to purify the process gas;
a process gas distribution system fluidly coupled to the at least one purification module, the process gas distribution system operable to store and distribute the process gas;
at least one plasma generator fluidly coupled to the gas distribution system, the plasma generator operable to produce a fluorine plasma from the process gas; and
at least one process chamber fluidly coupled to the at least one plasma generator, the fluorine plasma operable to clean the at least one vapor deposition process chamber.

38. The system of claim 37, wherein:
a plasma distribution system fluidly couple the at least one plasma generator to the at least one process chamber.

39. The system of claim 37, wherein:
the at least one vapor deposition process chamber is located within at least one process tool:
the at least one plasma generator is external to the process tool; and
the at least one plasma generator fluidly couples to a plurality of process tools.

40. The system of claim 39, wherein the system supplies fluorine plasma to a set of process tools within a fabrication facility.

41. The system of claim 39, wherein the system supplies fluorine plasma to a set of process tools within a process bay within a fabrication facility.

42. The system of claim 37, wherein the gas distribution system comprises:
at least one process gas storage tank fluidly coupled to the at least one purification module operable to receive and store the process gas; and
distribution lines that fluidly couple the at least one process gas storage tank to at least one plasma generator.

43. The system of claim 37, wherein the process chambers are located within multiple process tools, the process tool comprising at least one process tool selected from the group consisting of:
deposition processing tools;
Chemical Vapor Deposition (CVD) process tools;
Low Pressure Chemical Vapor Deposition (LPCVD) process tools;
Plasma Enhanced Chemical Vapor Deposition (PECVD) process tools;
Vapor Phase Epitaxy (VPE) process tools;
Metalorganic Chemical Vapor Deposition (MOCVD) process tools;
Physical Vapor Deposition (PVD) process tools;
thin-film deposition process tools;
ion implant process tools;
Plasma Etch process tools;
Etch process tools; and
Lithography process tools.

44. A method comprising:
generating a substantially pure process gas with a fluorine generating system;
coupling the fluorine generating system to a fluorine distribution system, the fluorine distribution system operable to receive the process gas;
coupling a plasma generator to the fluorine distribution system, the plasma generator operable to produce a fluorine plasma from the process gas;
coupling a plasma distribution system to the plasma generator, the plasma distribution system operable to receive the fluorine plasma;
coupling at least one process chamber to the plasma distribution system, the at least one process chamber receives the fluorine plasma from the plasma distribution system; and
cleaning individual process chambers with the fluorine plasma after a forming a predetermined number of processes within the individual process chamber.

45. The method of claim 44 wherein the processes comprise vapor deposition processes or etch processes.

46. The method of claim 44, wherein:
the at least one process chamber is located within at least one process tool:
the at least one plasma generator is external to the process tool; and
the at least one plasma generator fluidly couples to a plurality of process tools.

47. The method of claim 44, wherein the system supplies fluorine plasma to a set of process tools within a fabrication facility.

48. The method of claim 44, wherein the system supplies fluorine plasma to a set of process tools within a process bay within a fabrication facility.

49. The method of claim 44, wherein deposition layers are deposited on substrates within the process chambers, and devices are formed on the substrates.

50. The method of claim 49, wherein the devices comprise a semiconductor device selected from the groups consisting of:
microelectronic devices;
integrated microelectronic circuits;
ceramic substrate based devices;
flat panel displays;
microelectronic device substrates;
thin-film transistor (“TFT”) displays substrates; and
organic light-emitting diodes (“OLEDs”) substrates.

51. The method of claim 44, further comprising purifying the process gas to remove solids and HF.

52. A fluorine plasma generation system operable to service multiple process tools within a fabrication facility comprising:
a fluorine generating system operable to produce a process gas comprising diatomic fluorine from a fluorine-containing reactant;
a fluorine distribution system coupled to the fluorine generating system, the fluorine distribution system operable to receive the process gas;
a plasma generator coupled to the fluorine distribution system, the plasma generator operable to produce a fluorine plasma from the process gas;
a plasma distribution system coupled to the plasma generator, the plasma distribution system operable to receive the fluorine plasma; and
a plurality of process chambers fluidly coupled to the plasma distribution system, the process chambers located within multiple process tools, and the plurality of process chambers operable to be cleaned with the fluorine plasma.

53. The fluorine plasma generation system of claim 52, the fluorine generating system comprising:
at least one electrolytic cell operable to generate the process gas from a fluorine-containing reactant; and
a purification system operable to purify the process gas.

54. The fluorine plasma generation system of claim 52, wherein:
a plasma distribution system fluidly couple the at least one plasma generator to the at least one process chamber.

55. The fluorine plasma generation system of claim 54, wherein the process chambers are located within multiple process tools, the process tool comprising at least one process tool selected from the group consisting of:
deposition processing tools;
Chemical Vapor Deposition (CVD) process tools;
Low Pressure Chemical Vapor Deposition (LPCVD) process tools;
Plasma Enhanced Chemical Vapor Deposition (PECVD) process tools;
Vapor Phase Epitaxy (VPE) process tools;
Metalorganic Chemical Vapor Deposition (MOCVD) process tools;
Physical Vapor Deposition (PVD) process tools;
thin-film deposition process tools;
ion implant process tools;
Plasma Etch process tools;
Etch process tools; and
Lithography process tools.

56. The fluorine plasma generation system of claim 52, wherein deposition layers are deposited on substrates within the process chambers, and devices are formed on the substrates

57. The fluorine plasma generation system of claim 56, wherein the devices comprise a semiconductor device selected from the groups consisting of:
microelectronic devices;
integrated microelectronic circuits;
ceramic substrate based devices;
flat panel displays;
microelectronic device substrates;
thin-film transistor (“TFT”) displays substrates; and
organic light-emitting diodes (“OLEDs”) substrates.
the system supplies fluorine plasma to a set of process tools within a process bay within a fabrication facility.

58. A device comprising:
a substrate;
at least one deposited layer on the substrate, the layers processed within process chambers,
the process chamber cleaned with a fluorine plasma after a forming a predetermined number of deposition or etch processes,
the fluorine plasma received by the process chamber from a fluorine plasma generation and distribution system coupled to the process chamber.

59. The device of claim 61, the fluorine plasma generation and distribution system comprising:
a fluorine generating system operable to produce a process gas comprising diatomic fluorine from a fluorine-containing reactant;
a fluorine distribution system coupled to the fluorine generating system, the fluorine distribution system operable to receive the process gas;
a plasma generator coupled to the coupling the fluorine distribution system, the plasma generator operable to produce a fluorine plasma from the process gas;
the plasma distribution system couple to the plasma generator, the plasma distribution system operable to receive the fluorine plasma; and
the process chamber fluidly coupled to the plasma distribution system.

60. The device of claim 58, the substrate comprising a substrate selected from the groups consisting of:
semiconductor wafers;
microelectronic device substrates;
thin-film transistor (“TFT”) display substrates;
organic light-emitting diodes (“OLED”) substrates; and
glass plates.

61. The device of claim 58, the device comprising a semiconductor device selected from the groups consisting of:
microelectronic devices;
integrated microelectronic circuits;
ceramic substrate based devices;
flat panel displays;
microelectronic device substrates;
thin-film transistor (“TFT”) displays substrates; and
organic light-emitting diodes (“OLEDs”) substrates.

62. A method comprising:
forming layers of a semiconductor device within a process chamber;
generating a substantially pure process gas with a fluorine generating system;
coupling the fluorine generating system to a fluorine distribution system, the fluorine distribution system operable to receive the process gas;
coupling a plasma generator to the fluorine distribution system, the plasma generator operable to produce a fluorine plasma from the process gas;
coupling a plasma distribution system to the plasma generator, the plasma distribution system operable to receive the fluorine plasma;
coupling at least one process chamber to the plasma distribution system, the at least one process chamber receives the fluorine plasma from the plasma distribution system; and
cleaning the process chamber with the fluorine plasma after a forming a predetermined number of layers of a semiconductor device within a process chamber.
